(19) United States
(12) Patent Application Publication
(10) Pub. No.: US 2023/0223290 A1
(43) Pub. Date: Jul. 13, 2023

(54) DEVICE AND METHOD FOR WAFER BONDING ALIGNMENT

(71) Applicant: CHANGXIN MEMORY TECHNOLOGIES, INC., Hefei City (CN)

(72) Inventor: Chih-Wei CHANG, Hefei City (CN)

(73) Assignee: CHANGXIN MEMORY TECHNOLOGIES, INC., Hefei City (CN)

(21) Appl. No.: 18/169,826

(22) Filed: Feb. 15, 2023

Related U.S. Application Data
(63) Continuation of application No. PCT/CN2022/076141, filed on Feb. 14, 2022.

(30) Foreign Application Priority Data
Jan. 11, 2022 (CN) 202210027152.5

(51) Int. Cl. H01L 21/68

(52) U.S. Cl. CPC H01L 21/681; H01L 21/67092

(57) ABSTRACT

A device for wafer bonding alignment includes: a first fixing apparatus, configured to fix a first wafer, a first alignment mark being disposed on the first wafer; a second fixing apparatus, configured to fix a second wafer, a second alignment mark being disposed on the second wafer, the second fixing apparatus being disposed opposite to the first fixing apparatus; a reflection apparatus, located between the first fixing apparatus and the second fixing apparatus; and a mark reader, reading position information of the first alignment mark and the second alignment mark using the reflection apparatus to align the first wafer fixed on the first fixing apparatus and the second wafer fixed on the second fixing apparatus.

### CROSS-REFERENCE TO RELATED APPLICATIONS

This is a continuation of International Patent Application No. PCT/CN2022/076141 filed on Feb. 14, 2022, which claims priority to Chinese Patent Application No. 202210027152.5 filed on Jan. 11, 2022. The disclosures of the above-referenced applications are hereby incorporated by reference in their entirety.

### BACKGROUND

A semiconductor bonding technology refers to a technology of directly bonding two pieces of homogeneous or heterogeneous semiconductor materials after surface cleaning and activation treatment under certain conditions, and bonding wafers into one by Van der Waals force, molecular force or even atomic force. In an existing semiconductor technology, in order to increase the yield of a wafer, wafer-to-wafer bonding technology becomes the core focus. In the wafer bonding technology, wafer alignment accuracy and wafer distortion after bonding are important parameters to characterize the quality of a wafer bonding process. If there is a defect in the alignment accuracy in the wafer bonding process, the latter process will be seriously affected, then the connection and functionality of a circuit after wafer bonding will be affected, and the wafer yield will be reduced. Therefore, the wafer alignment accuracy is particularly critical.

### SUMMARY

The present disclosure relates to the technology of wafer packaging processing, and particularly to a device for wafer bonding alignment and a method for wafer bonding alignment.

Embodiments of the disclosure provide a device for wafer bonding alignment and a method for wafer bonding alignment.

According to a first aspect of the embodiments of the disclosure, a device for wafer bonding alignment is provided, which may include: a first fixing apparatus, a second fixing apparatus, a reflection apparatus, and a mark reader.

The first fixing apparatus is configured to fix a first wafer, a first alignment mark being disposed on the first wafer.

The second fixing apparatus is configured to fix a second wafer, a second alignment mark being disposed on the second wafer, and the second fixing apparatus being disposed opposite to the first fixing apparatus.

The reflection apparatus is located between the first fixing apparatus and the second fixing apparatus.

The mark reader reads position information of the first alignment mark and the second alignment mark using the reflection apparatus to align the first wafer fixed on the first fixing apparatus and the second wafer fixed on the second fixing apparatus.

According to a second aspect of the embodiments of the disclosure, a method for wafer bonding alignment is provided using a device as described in any of the above embodiments, which may include the following operations.

A first wafer is fixed to a first fixing apparatus, a first alignment mark being disposed on the first wafer.

A second wafer is fixed to a second fixing apparatus, a second alignment mark being disposed on the second wafer, and the second fixing apparatus being disposed opposite to the first fixing apparatus.

A reflection apparatus is disposed between the first fixing apparatus and the second fixing apparatus.

A mark reader is provided. The mark reader reads position information of the first alignment mark and the second alignment mark using the reflection apparatus to align the first wafer fixed on the first fixing apparatus and the second wafer fixed on the second fixing apparatus.

### BRIEF DESCRIPTION OF THE DRAWINGS

FIG. 1 is a structural schematic diagram of a device for wafer bonding alignment according to some embodiments of the disclosure.

FIG. 2 is a schematic diagram of a first alignment mark according to some embodiments of the disclosure.

FIG. 3 is a solid diagram of a reflection apparatus in a device for wafer bonding alignment according to some embodiments of the disclosure.

FIG. 4 is a flowchart of a method for wafer bonding alignment according to some embodiments of the disclosure.

FIG. 5A is a first schematic diagram of an alignment process of a method for wafer bonding alignment according to some embodiments of the disclosure.

FIG. 5B is a second schematic diagram of an alignment process of a method for wafer bonding alignment according to some embodiments of the disclosure.

### DETAILED DESCRIPTION

In some embodiments of the disclosure, the mark reader uses the reflection apparatus to read the position information of the first alignment mark and the second alignment mark, so as to align the first wafer and the second wafer. Thus, the mark reader does not need to move and only the wafer needs to be slightly moved to complete the alignment, thus improving the stability and accuracy of wafer alignment.

The following clearly describes the exemplary implementations disclosed by the embodiments of the disclosure with reference to the drawings. Although the drawings show exemplary implementations of the disclosure, it is to be understood that the disclosure may be implemented in various forms and shall not be limited by specific implementations described herein. On the contrary, providing these implementations is to understand the disclosure thoroughly, and the scope of the disclosure can be completely conveyed to technicians in the art.

A number of specific details are given below to provide a more thorough understanding of the disclosure. However, it is apparent to those skilled in the art that the disclosure may be implemented without one or more of these details. In other examples, to avoid confusion with the disclosure, some technical features known in the art are not described; namely, all the features of the actual embodiments are not described here, nor are known functions and structures described in detail.

In the drawings, dimensions of layers, areas, components and their relative dimensions may be exaggerated for clarity. The same drawing marks throughout represent the same components.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, regions, layers and/or parts may be described with terms first, second, third, etc., these elements, components, regions, layers and/or parts should not be limited to these terms. These terms are used only to distinguish one element, component, region, layer or part from another element, component, region, layer or part. Therefore, a first element, component, region, layer or part discussed below may be represented as a second element, component, region, layer or part without departing from the teaching of the disclosure. However, when discussing a second element, component, region, layer or part, it does not necessarily imply the existence of a first element, component, region, layer or part of the disclosure.

Spatially relational terms such as “below”, “under”, “lower”, “beneath”, “above”, and “upper” may be used herein for convenience of description to describe a relationship between one element or feature and another element or feature illustrated in the drawings. It is to be understood that, in addition to the orientation shown in the figures, the spatially relational terms are intended to further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower. The device may be otherwise oriented (rotated by 90 degrees or in other orientations) and the spatial descriptors used herein may be interpreted accordingly.

The terms used herein are for the purpose of describing specific embodiments only and not intended to limit the disclosure. As used herein, singular forms “a/an”, “one”, and “the” are also intended to include the plural forms, unless otherwise specified in the context. It is also to be understood that, when terms “composed of” and/or “including” are used in this specification, the presence of the features, integers, steps, operations, elements, and/or components is determined, but the presence or addition of one or more other features, integers, steps, operations, elements, components, and/or groups is also possible. As used herein, term “and/or” includes any and all combinations of the related listed items.

In order to thoroughly understand the disclosure, detailed steps and detailed structure will be presented in the following description to explain the technical solution of the disclosure. Optional embodiments of the disclosure are described in details below, however in addition to these detailed descriptions, and the disclosure may have other implementation modes.

The reference numbers in the drawings are illustrated below: 1—First fixing apparatus, 2—Second fixing apparatus, 10—First wafer, 11—First alignment mark, 20—Second wafer, 21—Second alignment mark, 3—Reflection apparatus, 31—First reflection surface, 32—Second reflection surface, 4—Mark reader, and 5—Calculation apparatus.

In some implementations, two cameras are used to align an upper wafer and a lower wafer respectively. This design leads to the need for the two cameras to correct an alignment point during heterogeneous bonding alignment. In addition, when the wafer is aligned, a great transverse movement is required, which also affects the alignment accuracy. In addition, using two cameras may also increase the cost.

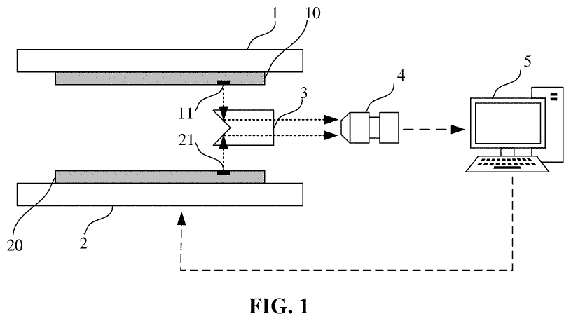

Based thereon, the embodiments of the disclosure provide a device for wafer bonding alignment. FIG. 1 is a structural schematic diagram of a device for wafer bonding alignment according to some embodiments of the disclosure.

Referring to FIG. 1, the device for wafer bonding alignment includes a first fixing apparatus 1, a second fixing apparatus 2, a reflection apparatus 3, and a mark reader 4.

The first fixing apparatus 1 is configured to fix a first wafer 10. A first alignment mark 11 is disposed on the first wafer 10. The second fixing apparatus 2 is configured to fix a second wafer 20. A second alignment mark 21 is disposed on the second wafer 20. The second fixing apparatus 2 is disposed opposite to the first fixing apparatus 1. The reflection apparatus 3 is located between the first fixing apparatus 1 and the second fixing apparatus 2. The mark reader 4 reads position information of the first alignment mark 11 and the second alignment mark 21 using the reflection apparatus 3 to align the first wafer 10 fixed on the first fixing apparatus 1 and the second wafer 20 fixed on the second fixing apparatus 2.

In some embodiments of the disclosure, the mark reader uses the reflection apparatus to read the position information of the first alignment mark and the second alignment mark, so as to align the first wafer and the second wafer. Thus, the mark reader does not need to move and only the wafer needs to be slightly moved to complete the alignment, thus improving the stability and accuracy of wafer alignment. Furthermore, in some embodiments of the disclosure, only one mark reader is used, which saves the cost.

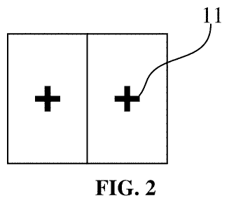

FIG. 2 is a schematic diagram of a first alignment mark according to some embodiments of the disclosure. The first alignment mark 11 shown in the figure is cross-shaped. In other embodiments, the first alignment mark may be line-shaped, circular or ring-shaped. Only the first alignment mark 11 is shown in FIG. 2, and the second alignment mark 21 has the same shape as the first alignment mark 11. In some embodiments of the disclosure, the shapes of the first alignment mark 11 and the second alignment mark 21 are not particularly limited but depend on the practical design requirements.

The materials of the first alignment mark 11 and the second alignment mark 21 are metals or other materials which are sensitive to light, so that the light sensitivity of the first alignment mark 11 and the second alignment mark 21 is enhanced, and the reading accuracy is further improved.

In some embodiments of the disclosure, the first wafer 10 and the second wafer 20 are moved, so that the first alignment mark 11 and the second alignment mark 21 are located at a central position of the field of view of the mark reader 4, so as to achieve the purpose of aligning the first wafer 10 fixed on the first fixing apparatus 1 and the second wafer 20 fixed on the second fixing apparatus 2.

In one embodiment, the operation that the mark reader 4 reads position information of the first alignment mark 11 and the second alignment mark 21 using the reflection apparatus 3 includes that: position information of the first alignment mark 11 and position information of the second alignment mark 21 are read simultaneously. Reading the position information of the first alignment mark and the second alignment mark simultaneously may improve the stability and accuracy during information reading compared to reading the position information of the first alignment mark and the second alignment mark separately. However, it is to be understood that in other embodiments, the position information of the first alignment mark and the second alignment mark may be read separately.

In one embodiment, both the number of the first alignment marks 11 and the number of the second alignment marks 21 are greater than or equal to two. Two or more first alignment marks and second alignment marks may give consideration to both the lateral and longitudinal alignment accuracy during alignment, thereby improving the accuracy of wafer alignment.

The number of the first alignment marks 11 may be equal to the number of the second alignment marks 21.

In the present embodiment, the mark reader 4 is an optical reader. The optical reader is configured to emit light to directly read the position information of the first alignment mark 11 or the second alignment mark 21 when the first fixing apparatus 1 or the second fixing apparatus 2 is moved to a preset position. Moreover, the light emitted from the mark reader 4 is far infrared light. When the light emitted from the mark reader 4 is the far infrared light, the penetrating power of the light emitted from the mark reader 4 is strong, so that the reading capability of the mark reader 4 can be improved.

Specifically, the operation that the mark reader 4 reads the position information of the first alignment mark 11 and the second alignment mark 21 using the reflection apparatus 3 includes that: detection light is incident on the first alignment mark 11 and the second alignment mark 21. The first alignment mark 11 and the second alignment mark 21 reflect the detection light, and the reflected detection light enters the mark reader 4 after being reflected by the reflection apparatus 3 so as to read the position information of the first alignment mark 11 and the second alignment mark 21.

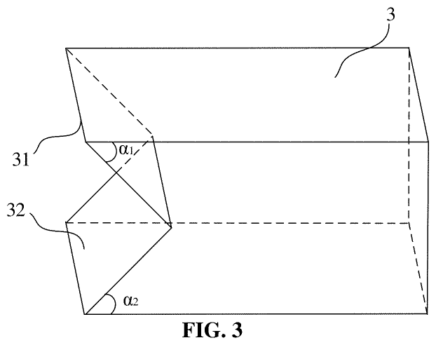

FIG. 3 is a solid diagram of a reflection apparatus in a device for wafer bonding alignment according to some embodiments of the disclosure. In some embodiments of the disclosure, the reflection apparatus 3 resembles a reflective glass of a single reflex camera.

In one embodiment, the reflection apparatus 3 includes a first reflection surface 31 and a second reflection surface 32. The detection light reflected by the first alignment mark 11 enters the mark reader 4 after being reflected by the first reflection surface 31. The detection light reflected by the second alignment mark 21 enters the mark reader 4 after being reflected by the second reflection surface 32.

Continuing to refer to FIG. 3, the reflection apparatus 3 is Σ-shaped.

A reflection layer is formed on the first reflection surface 31 and the second reflection surface 32. Specifically, the surfaces of outer layers of the first reflection surface 31 and the second reflection surface 32 are coated with the reflection layers so that the detection light, when reflected to the surfaces of inner layers of the first reflection surface 31 and the second reflection surface 32, does not directly pass through the first reflection surface and the second reflection surface but is reflected to the reader marker.

An included angle between the first reflection surface and the plane of the first wafer is 45°. An included angle between the second reflection surface and the plane of the second wafer is 45°.

Specifically, referring to FIG. 3, the included angle between the first reflection surface 31 and the plane of the first wafer 10 is α₁ in the figure, and the included angle between the second reflection surface 32 and the plane of the second wafer 20 is α₂ in the figure. The α₁ and α₂ are set to be 45°. When the detection light is vertically reflected to the first reflection surface and the second reflection surface, the reflected detection light is horizontally reflected to the mark reader, so as to ensure the accuracy of the read position information and improve the accuracy of alignment.

In one embodiment, the device for wafer bonding alignment further includes: a calculation apparatus 5, configured to calculate the position information of the first alignment mark 11 and the second alignment mark 21 read by the mark reader 4, and align the first wafer 10 fixed on the first fixing apparatus 1 and the second wafer 20 fixed on the second fixing apparatus 2 according to a calculation result.

Specifically, the calculation apparatus 5 calculates an offset between the position information of the first alignment mark 11 and the second alignment mark 21 read by the mark reader 4 and the central position of the field of view of the mark reader, and moves the first fixing apparatus 1 or the second fixing apparatus 2 according to the calculation result, so as to align the first wafer 10 and the second wafer 20.

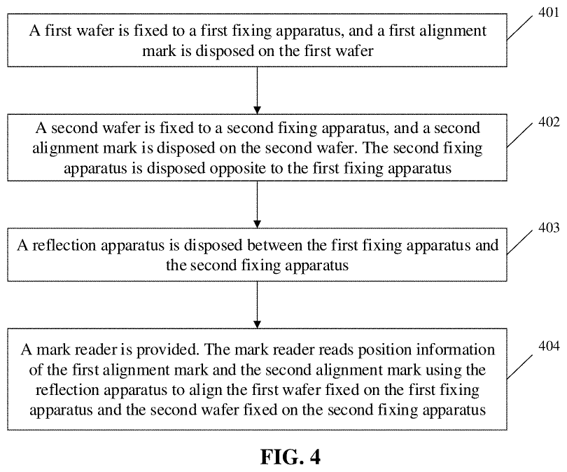

The embodiments of the disclosure further provide a method for wafer bonding alignment using a device as described in any of the above embodiments, specifically referring to FIG. 4, as shown in the figure, the method including the following steps.

At S401, a first wafer is fixed to a first fixing apparatus, and a first alignment mark is disposed on the first wafer.

At S402, a second wafer is fixed to a second fixing apparatus, and a second alignment mark is disposed on the second wafer. The second fixing apparatus is disposed opposite to the first fixing apparatus.

At S403, a reflection apparatus is disposed between the first fixing apparatus and the second fixing apparatus.

At 5404, a mark reader is provided. The mark reader reads position information of the first alignment mark and the second alignment mark using the reflection apparatus to align the first wafer fixed on the first fixing apparatus and the second wafer fixed on the second fixing apparatus.

Further detailed description is made to the method for wafer bonding alignment in the embodiment of the disclosure below with reference to specific embodiments.

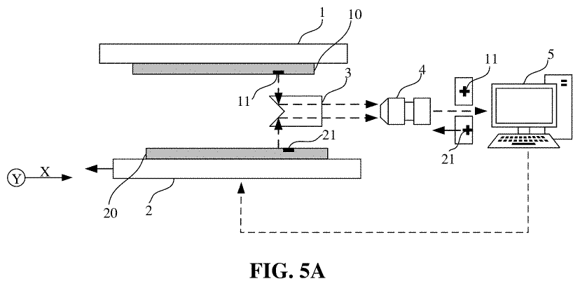

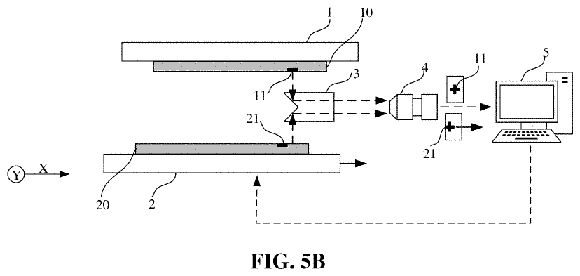

FIG. 5A and FIG. 5B are schematic diagrams of an alignment process of a method for wafer bonding alignment according to some embodiments of the disclosure.

First, referring to FIG. 5A, S401-S402 are executed. A first wafer 10 is fixed to a first fixing apparatus 1. A first alignment mark 11 is disposed on the first wafer 10. A second wafer 20 is fixed to a second fixing apparatus 2. A second alignment mark 21 is disposed on the second wafer 20. The second fixing apparatus 2 is disposed opposite to the first fixing apparatus 1.

FIG. 2 is a schematic diagram of a first alignment mark according to some embodiments of the disclosure. The first alignment mark 11 shown in the figure is cross-shaped. In other embodiments, the first alignment mark may be line-shaped, circular or ring-shaped. Only the first alignment mark 11 is shown in FIG. 2, and the second alignment mark 21 has the same shape as the first alignment mark 11. In the embodiments of the disclosure, the shapes of the first alignment mark 11 and the second alignment mark 21 are not particularly limited but depend on the design requirements.

The materials of the first alignment mark 11 and the second alignment mark 21 are metals or other materials which are sensitive to light, so that the light sensitivity of the first alignment mark 11 and the second alignment mark 21 is enhanced, and the reading accuracy is further improved.

In some embodiments of the disclosure, the first wafer 10 and the second wafer 20 are moved, so that the first alignment mark 11 and the second alignment mark 21 are located at a central position of the field of view of the mark reader 4, so as to achieve the purpose of aligning the first wafer 10 fixed on the first fixing apparatus 1 and the second wafer 20 fixed on the second fixing apparatus 2.

In one embodiment, both the number of the first alignment marks 11 and the number of the second alignment marks 21 are greater than or equal to two. Two or more first alignment marks and second alignment marks may give consideration to both the lateral and longitudinal alignment accuracy during alignment, thereby improving the accuracy of wafer alignment.

The number of the first alignment marks 11 may be equal to the number of the second alignment marks 21.

Continuing to refer to FIG. 5A, S403 is executed. A reflection apparatus 3 is disposed between the first fixing apparatus 1 and the second fixing apparatus 2.

FIG. 3 is a solid diagram of a reflection apparatus in a device for wafer bonding alignment according to some embodiments of the disclosure. In some embodiments of the disclosure, the reflection apparatus 3 resembles a reflective glass of a single reflex camera.

In one embodiment, the reflection apparatus 3 is Σ-shaped.

Continuing to refer to FIG. 3, the reflection apparatus 3 includes a first reflection surface 31 and a second reflection surface 32.

A reflection layer is formed on the first reflection surface 31 and the second reflection surface 32. Specifically, the surfaces of outer layers of the first reflection surface 31 and the second reflection surface 32 are coated with the reflection layers so that the detection light, when reflected to the surfaces of inner layers of the first reflection surface 31 and the second reflection surface 32, does not directly pass through the first reflection surface and the second reflection surface but is reflected to the reader marker.

An included angle between the first reflection surface and the plane of the first wafer is 45°. An included angle between the second reflection surface and the plane of the second wafer is 45°.

Specifically, referring to FIG. 3, the included angle between the first reflection surface 31 and the plane of the first wafer 10 is α₁ in the figure, and the included angle between the second reflection surface 32 and the plane of the second wafer 20 is α₂ in the figure. The α₁ and α₂ are set to be 45°. When the detection light is vertically reflected to the first reflection surface and the second reflection surface, the reflected detection light is horizontally reflected to the mark reader, so as to ensure the accuracy of the read position information and improve the accuracy of alignment.

Continuing to refer to FIG. 5A, S404 is executed. A mark reader 4 is provided.

The mark reader 4 reads position information of the first alignment mark 11 and the second alignment mark 21 using the reflection apparatus 3 to align the first wafer 10 fixed on the first fixing apparatus 1 and the second wafer 20 fixed on the second fixing apparatus 2.

In one embodiment, the operation that the mark reader 4 reads position information of the first alignment mark 11 and the second alignment mark 21 using the reflection apparatus 3 includes that: position information of the first alignment mark 11 and position information of the second alignment mark 21 are read simultaneously. Reading the position information of the first alignment mark and the second alignment mark simultaneously may improve the stability and accuracy during information reading compared to reading the position information of the first alignment mark and the second alignment mark separately. However, it is to be understood that in other embodiments, the position information of the first alignment mark and the second alignment mark may be read separately.

In the present embodiment, the mark reader 4 is an optical reader. The optical reader is configured to emit light to directly read the position information of the first alignment mark 11 or the second alignment mark 21 when the first fixing apparatus 1 or the second fixing apparatus 2 is moved to a preset position. Moreover, the light emitted from the mark reader 4 is far infrared light. When the light emitted from the mark reader 4 is the far infrared light, the penetrating power of the light emitted from the mark reader 4 is strong, so that the reading capability of the mark reader 4 can be improved.

Specifically, the operation that the mark reader 4 reads the position information of the first alignment mark 11 and the second alignment mark 21 using the reflection apparatus 3 includes that: detection light is incident on the first alignment mark 11 and the second alignment mark 21. The first alignment mark 11 and the second alignment mark 21 reflect the detection light, and the reflected detection light enters the mark reader 4 after being reflected by the reflection apparatus 3 so as to read the position information of the first alignment mark 11 and the second alignment mark 21.

In one embodiment, the detection light reflected by the first alignment mark 11 enters the mark reader 4 after being reflected by the first reflection surface 31. The detection light reflected by the second alignment mark 21 enters the mark reader 4 after being reflected by the second reflection surface 32.

After the mark reader 4 reads the position information of the first alignment mark 11 and the second alignment mark 21 using the reflection apparatus 3, the method further includes the following operations.

A calculation apparatus 5 is provided. The calculation apparatus 5 calculates the position information of the first alignment mark 11 and the second alignment mark 12 read by the mark reader 4 and aligns the first wafer 10 fixed on the first fixing apparatus 1 and the second wafer 20 fixed on the second fixing apparatus 2 according to the calculation result.

Specifically, the calculation apparatus 5 calculates an offset between the position information of the first alignment mark 11 and the second alignment mark 21 read by the mark reader 4 and the central position of the field of view of the mark reader 4, and moves the first fixing apparatus 1 or the second fixing apparatus 2 according to the calculation result, so as to align the first wafer 10 and the second wafer 20.

In the present embodiment, the first fixing apparatus or the second fixing apparatus is moved in the X or Y direction to align the first wafer and the second wafer. As shown in FIG. 5A and FIG. 5B, the alignment process of the first wafer 10 and the second wafer 20 is described by taking moving the second fixing apparatus 2 in the X direction as an example.

As shown in FIG. 5A, when the mark reader 4 reads that the first alignment mark 11 is located at the central position of the field of view of the mark reader 4 and the position of the second alignment mark 21 is offset to the right side of the field of view of the mark reader 4 in the X direction, the calculation apparatus 5 calculates an offset between the position information of the second alignment mark 21 read by the mark reader 4 and the central position of the field of view of the mark reader 4, and according to a calculation result, moves the second fixing apparatus 2 to the left in the X direction until the second alignment mark 21 is located at the central position of the field of view of the mark reader 4. At this time, the alignment process of the first wafer 10 and the second wafer 20 is completed, the reflection apparatus 3 is removed, and the first wafer 10 and the second wafer 20 are bonded.

As shown in FIG. 5B, when the mark reader 4 reads that the first alignment mark 11 is located at the central position of the field of view of the mark reader 4 and the position of the second alignment mark 21 is offset to the left side of the field of view of the mark reader 4 in the X direction, the calculation apparatus 5 calculates an offset between the position information of the second alignment mark 21 read by the mark reader 4 and the central position of the field of view of the mark reader 4, and according to a calculation result, moves the second fixing apparatus 2 to the right in the X direction until the second alignment mark 21 is located at the central position of the field of view of the mark reader 4. At this time, the alignment process of the first wafer 10 and the second wafer 20 is completed, the reflection apparatus 3 is removed, and the first wafer 10 and the second wafer 20 are bonded.

It is to be noted that in FIG. 5A and FIG. 5B, only an example of moving the second fixing apparatus in the X direction is shown, but the alignment process of the first wafer and the second wafer further includes a process of moving the first fixing apparatus and the second fixing apparatus in the Y direction.

The above is only preferred embodiments of the disclosure and not intended to limit the protection scope of the disclosure. Any modifications, equivalent replacements, improvements and the like made within the spirit and principle of the disclosure shall fall within the protection scope of the disclosure.

In the embodiments of the disclosure, a mark reader uses a reflection apparatus to read the position information of a first alignment mark and a second alignment mark, so as to align a first wafer and a second wafer. Thus, the mark reader does not need to move and only the wafer needs to be slightly moved to complete the alignment, thus improving the stability and accuracy of wafer alignment.

What is claimed is:

1. A device for wafer bonding alignment, comprising:
a first fixing apparatus, configured to fix a first wafer, a first alignment mark being disposed on the first wafer;
a second fixing apparatus, configured to fix a second wafer, a second alignment mark being disposed on the second wafer, and the second fixing apparatus being disposed opposite to the first fixing apparatus;
a reflection apparatus, located between the first fixing apparatus and the second fixing apparatus; and
a mark reader, configured to read position information of the first alignment mark and the second alignment mark using the reflection apparatus to align the first wafer fixed on the first fixing apparatus and the second wafer fixed on the second fixing apparatus.

2. The device for wafer bonding alignment of claim 1, wherein the mark reader is further configured to read the position information of the first alignment mark and the second alignment mark at a same time.

3. The device for wafer bonding alignment of claim 1, wherein
a number of the first alignment marks and a number of the second alignment marks are both greater than or equal to two.

4. The device for wafer bonding alignment of claim 1, wherein
the first alignment mark and the second alignment mark are further configured to acquire incident detection light and reflect the detection light to the reflection apparatus,
the reflection apparatus is further configured to reflect the reflected detection light to the mark reader, and
the mark reader is further configured to acquire the reflected detection light that is reflected by the reflection apparatus so as to read the position information of the first alignment mark and the second alignment mark.

5. The device for wafer bonding alignment of claim 4, wherein
the reflection apparatus comprises a first reflection surface and a second reflection surface,
detection light reflected by the first alignment mark enters the mark reader after being reflected by the first reflection surface, and
detection light reflected by the second alignment mark enters the mark reader after being reflected by the second reflection surface.

6. The device for wafer bonding alignment of claim 5, wherein
the reflection apparatus is Σ-shaped.

7. The device for wafer bonding alignment of claim 5, wherein
an included angle between the first reflection surface and a plane of the first wafer is 45°,
an included angle between the second reflection surface and a plane of the second wafer being 45°.

8. The device for wafer bonding alignment of claim 5, wherein
a reflection layer is formed on the first reflection surface and the second reflection surface.

9. The device for wafer bonding alignment of claim 1, further comprising:
a calculation apparatus, configured to calculate the position information of the first alignment mark and the second alignment mark read by the mark reader, and align the first wafer fixed on the first fixing apparatus and the second wafer fixed on the second fixing apparatus according to a calculation result.

10. A method for wafer bonding alignment, performed by a device for wafer bonding alignment, comprising:
fixing a first wafer to a first fixing apparatus, a first alignment mark being disposed on the first wafer;
fixing a second wafer to a second fixing apparatus, a second alignment mark being disposed on the second wafer, and the second fixing apparatus being disposed opposite to the first fixing apparatus;
disposing a reflection apparatus between the first fixing apparatus and the second fixing apparatus; and
providing a mark reader, and reading, by the mark reader, position information of the first alignment mark and the second alignment mark using the reflection apparatus to align the first wafer fixed on the first fixing apparatus and the second wafer fixed on the second fixing apparatus.

11. The method of claim 10, wherein
reading, by the mark reader, position information of the first alignment mark and the second alignment mark using the reflection apparatus comprises:
reading, by the mark reader, the position information of the first alignment mark and the second alignment mark at a same time.

12. The method of claim 10, wherein
a number of the first alignment marks and a number of the second alignment marks are both greater than or equal to two.

13. The method of claim 10, wherein
reading, by the mark reader, position information of the first alignment mark and the second alignment mark using the reflection apparatus comprises:
acquiring, by the first alignment mark and the second alignment mark, incident detection light;
reflecting, by the first alignment mark and the second alignment mark, the detection light to the reflection apparatus;
reflecting, by the reflection apparatus, the reflected detection light to the mark reader; and
acquiring, by the mark reader, the reflected detection light that is reflected by the reflection apparatus so as to read the position information of the first alignment mark and the second alignment mark.

14. The method of claim 13, wherein
the reflection apparatus comprises a first reflection surface and a second reflection surface,
detection light reflected by the first alignment mark enters the mark reader after being reflected by the first reflection surface, and
detection light reflected by the second alignment mark enters the mark reader after being reflected by the second reflection surface.

15. The method of claim 14, wherein
the reflection apparatus is Σ-shaped.

16. The method of claim 14, wherein
an included angle between the first reflection surface and a plane of the first wafer is 45°,
an included angle between the second reflection surface and a plane of the second wafer being 45°.

17. The method of claim 14, wherein
a reflection layer is formed on the first reflection surface and the second reflection surface.

18. The method of claim 10, further comprising:
providing a calculation apparatus;
calculating, by the calculation apparatus, the position information of the first alignment mark and the second alignment mark read by the mark reader; and
aligning, by the calculation apparatus, the first wafer fixed on the first fixing apparatus and the second wafer fixed on the second fixing apparatus according to a calculation result.
